(19) United States
(12) Patent Application Publication
(10) Pub. No.: US 2005/0212014 A1
(43) Pub. Date: Sep. 29, 2005

(54) Semiconductor device and semiconductor sensor

(76) Inventors: Masahiro Horibe, Tsukuba (JP); Naoki Harada, Kawasaki (JP); Yoshitaka Yamaguchi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/971,699

(22) Filed: Oct. 25, 2004

(30) Foreign Application Priority Data
Mar. 26, 2004 (JP) PAT.2004-093076

(51) Int. Cl. H01L 29/76

(52) U.S. Cl. 257/213

(57) ABSTRACT

A semiconductor device includes a substrate; a gate electrode formed on the substrate; a gate insulating film covering the gate electrode; a carbon nanotube disposed above the gate electrode and coming in contact with the gate insulating film; and a source electrode and a drain electrode formed apart from one another in a longitudinal direction of the carbon nanotube.

### BACKGROUND OF THE INVENTION

1. Field of the Invention

The present invention relates to a semiconductor device having a channel made of a carbon nanotube, and a semiconductor sensor basically employing the same concept.

2. Description of the Related Art

Operation speed in a semiconductor device such as a field effect transistor (FET) is increased by means of miniaturization, i.e., shortening of a gate length and reducing of a thickness of a gate insulating film. However, it is said that a hyperfine structure technology in an FET employing a silicon substrate almost has a limitation on a line width of tens of nanometers.

In order to further increase operation speed in an FET, a carbon nanotube which enables high speed electron conduction has taken an attention.

The carbon nanotube has a single dimensional shape having a diameter approximately in a range between several nanometers and ten nanometers, and a length of several micrometers, and they say that, thanks to the shape, ballistic conduction, i.e., high speed conduction of electron without scattering may be carried out. An FET which applies this nature, and employs a carbon nanotube as a channel has been proposed. Since a carbon nanotube has a maximum current density of million A/cm², a sufficient drain current may be provided advantageously even when it is applied to an FET in a hyperfine structure.

FIGS. 1A and 1B show sectional views of semiconductor devices each employing such a carbon nanotube as a channel in the related art. As shown in FIG. 1A, a semiconductor device 100 has a structure in which, on a substrate 101 on which a silicon oxide 102 is formed, a carbon nanotube 103 is disposed. At both ends of the carbon nanotube 103, a source electrode 104 and a drain electrode 105 are provided, a gate oxide 106 covers the carbon nanotube 103, and further, a gate electrode 108 is formed. Such a structure is called ‘a top gate FET’.

Further, as shown in FIG. 1B, a semiconductor device 110 has a structure in which a gate oxide 106 is formed on a substrate 101, and a carbon nanotube 103 is provided thereon. At both ends of the carbon nanotube 103, a source electrode 104 and a drain electrode 105 are provided, and also, a gate electrode 111 is provided on a reverse side of the substrate 101. Such a structure is called ‘a back gate FET’.

As to the related art, see F. Nihei, et al., Jpn, J. Appl. Phys., Vol. 42 (2003), L-1288 through L-1291.

### SUMMARY FO THE INVENTION

However, in the back gate FET shown in FIG. 1B, since a gate voltage is applied to the entirety of the substrate 101 in the thickness direction, it is difficult to isolate adjacent FETs from one another.

Such a problem is solved in the top gate FET shown in FIG. 1A. However, in this structure, since the gate insulating film 106 and the gate electrode 108 are formed as well as the source electrode 104 and the drain electrode 105 after the carbon nanotube is formed, there is a possibility that the carbon nanotube may be chemically or physically damaged due to plasma or sputtering particles in a film formation process, a patterning process or such, and as a result, electrical or mechanical characteristics thereof may be deteriorated.

Furthermore, also assuming a case where an FET employing such a carbon nanotube as a channel is used as a semiconductor sensor for detecting molecules or such contained in liquid or gas in a manner such that the FET is exposed to the liquid or the gas, the same problem may occur.

The present invention has been devised in consideration of the above-mentioned problem, and, an object of the present invention is to provide a semiconductor device and a semiconductor sensor in which a damage otherwise a carbon nanotube would suffer in a manufacturing process thereof can be effectively reduced and thus superior characteristics may be provided thereby.

According to one aspect of the present invention, a semiconductor device includes a substrate; a gate electrode formed on the substrate; a gate insulating film covering the gate electrode; a carbon nanotube disposed above the gate electrode and coming into contact with the gate insulating film; and a source electrode and a drain electrode formed apart from one another in a longitudinal direction of the carbon nanotube and electrically connected with the carbon nanotube.

In this configuration, since the carbon nanotube is formed on the gate electrode and on the gate insulating film, it is possible to effectively avoid a situation which would otherwise occur in which, if a gate insulating film were formed after formation of a carbon nanotube, a damage would be applied to the carbon nanotube due to plasma, radical or such in a sputtering method, a CVD (chemical vapor deposition) method or such, and thus, an defective open hole or such would occur therein. As a result of such a damage being thus effectively avoided, it is possible to effectively avoid deterioration in electron mobility in the carbon nanotube acting as a channel. As a result, it is possible to provide a semiconductor device having superior operation characteristics.

According to another aspect of the present invention, a semiconductor sensor includes a substrate; a gate electrode formed on the substrate; an insulating film covering a surface of the substrate and a part of the gate electrode; a carbon nanotube disposed to come into contact with the insulating film; and a source electrode and a drain electrode formed apart from one another in a longitudinal direction of the carbon nanotube and electrically connected with the carbon nanotube, wherein the insulating film includes an empty space between the gate electrode and the carbon nanotube for exposing a surface of the gate electrode.

In the semiconductor sensor having this configuration, as a result of the surface of the sensor being exposed to liquid or gas which is a to-be-measured object, the liquid or gas inserted in the empty space of the insulating film, i.e., between the gate electrode surface and the carbon nanotube causes the dielectric constant there to change due to an influence of ions, dielectric matters or such contained in the liquid or gas. The change in the dielectric constant can thus be detected as a change in a drain current flowing between the source electrode and the drain electrode. In the back gate FET in the related art shown in FIG. 1B, the liquid or the gas as the to-be-measured object exists only above the carbon nanotube. In contrast thereto, in the semiconductor sensor according to the present invention described above, molecules or such of the to-be-measured object are inserted between the gate electrode surface and the carbon nanotube (in the empty space). Accordingly, it is possible to detect the molecules or such in the to-be-measured object with remarkably high sensitivity. Furthermore, according to the present invention, since the gate capacitance value and the drain current change approximately in proportion to the change in the dielectric constant due to the liquid or gas of the to-be-measured object, it is possible to detect the molecules or such of the to-be-measured object with a high sensitivity.

Thus, according to the present invention, it is possible to provide a semiconductor device or a semiconductor sensor having superior operation characteristics as a result of damage otherwise applied to a carbon nanotube in a manufacturing process thereof being effectively reduced.

### BRIEF DESCRIPTION OF THE DRAWINGS

Other objects and further features of the present invention will become more apparent from the following detailed description when read in conjunction with the accompanying drawings:

FIGS. 1A and 1B show elevational sectional views of semiconductor devices in the related art employing carbon nanotubes as channels;

FIG. 2 shows a perspective view of a semiconductor device according to a first embodiment of the present invention;

FIG. 3 shows an elevational sectional view of the semiconductor device according to the first embodiment;

FIGS. 4A through 4E and 5A through 5C show manufacturing processes for the semiconductor device according to the first embodiment;

FIG. 6 shows an elevational sectional view of a semiconductor device according to a second embodiment of the present invention;

FIG. 7 shows an elevational sectional view of a semiconductor device according to a third embodiment of the present invention;

FIGS. 8A through 8C show an elevational sectional view (8A), a sectional view taken along an A-A line of FIGS. 8A (8B) and a plan view (8C) of a semiconductor device according to a fourth embodiment of the present invention;

FIG. 9 shows a perspective view of a semiconductor sensor according to a fifth embodiment of the present invention;

FIG. 10 shows an elevational sectional view of the semiconductor sensor according to the fifth embodiment;

FIG. 11 shows an elevational sectional view of a semiconductor sensor according to a variant embodiment of the fifth embodiment of the present invention;

FIG. 12 shows an elevational sectional view of a semiconductor sensor according to a sixth embodiment of the present invention;

FIG. 13 shows a partial magnified view of the semiconductor sensor according to the sixth embodiment of the present invention; and

FIG. 14 shows an elevational sectional view of a semiconductor sensor according to a variant embodiment of the sixth embodiment of the present invention.

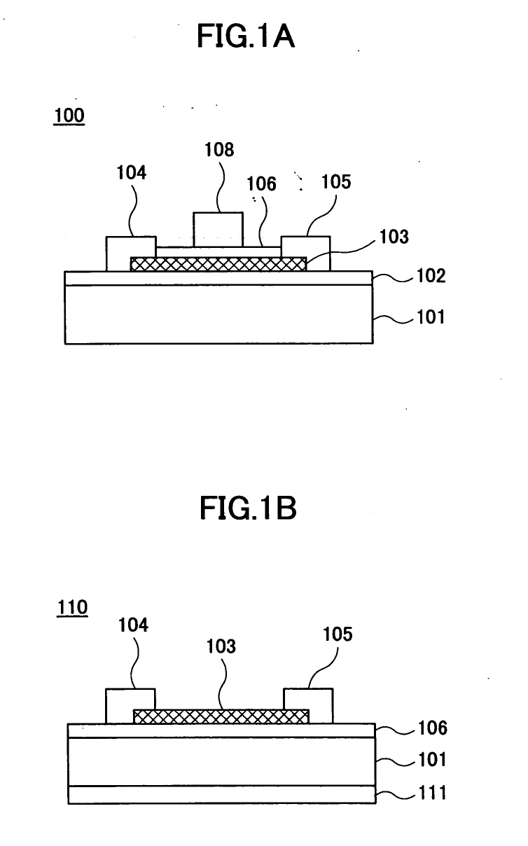

### DETAILED DESCRIPTION OF THE PREFERRED EMBODIMENTS

With reference to the figures, embodiments of the present invention will be described specifically one by one.

A first embodiment of the present invention is described.

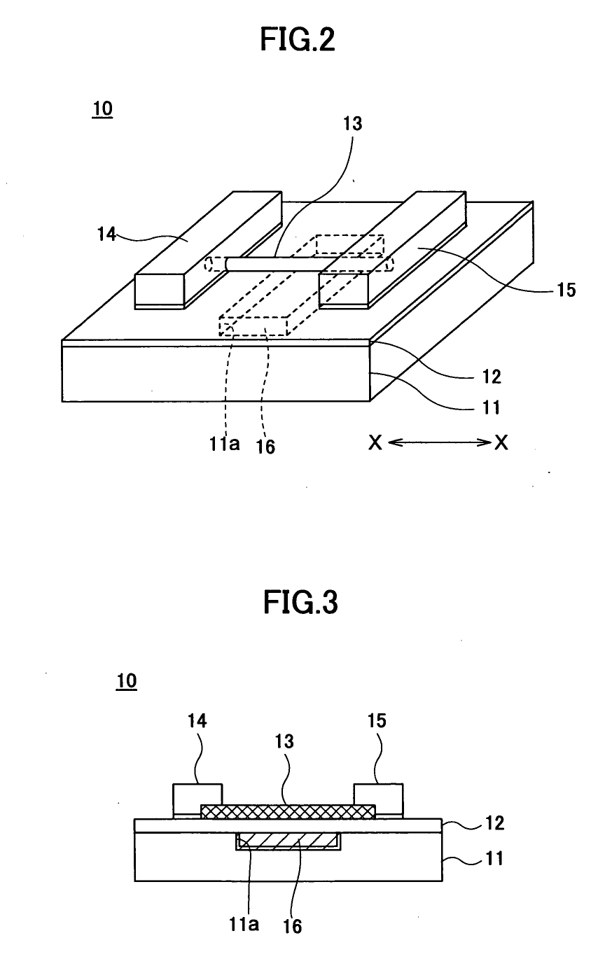

FIG. 2 shows a perspective view of a semiconductor device according to the first embodiment of the present invention, and FIG. 3 shows an elevational sectional view of the semiconductor device shown in FIG. 2 taken along an X direction.

As shown in FIGS. 2 and 3, the semiconductor device 10 according to the first embodiment of the present embodiment includes a substrate 11, a gate electrode 16 formed in a groove 11a formed in a surface of the substrate 11, a gate insulating film 12 covering a surface of the. substrate 11 and the gate electrode 16, a carbon nanotube 13 formed on the gate insulating film 12 in such a manner that a length direction of the gate electrode 16 coincides with a longitudinal direction (the X direction shown) of the carbon nanotube 13, and a source electrode 14 and a drain electrode 15 formed apart from one another along the longitudinal direction of the carbon nanotube 13 and in contact with the carbon nanotube 13.

In the semiconductor device 10, a voltage (gate voltage) applied to the gate electrode 16 is applied to the carbon nanotube 13 via the gate insulating film 12 as an electric field, the carbon nanotube formed between the source electrode 14 and the drain electrode 15 functions as a channel, and, a drain current flowing through the carbon nanotube 13 changes according to a change in the gate voltage applied.

Although material of the substrate 11 is not specially limited, it is preferable that it is a silicon substrate, or a III-V or a II-VI semiconductor substrate, or it is made from a high resistivity material or from an insulating material.

The gate electrode 16 is formed as a result of a Ti film (with a film thickness of 10 nm) and an Au film (with a film thickness of 490 nm) being laminated in the stated order in the groove 11a formed in the surface of the substrate 11. The Ti film functions as an adhesion film to adhere with the substrate 11, and is appropriately selected according to the material of the substrate 11. Instead of the Au film, another material such as Al, Ti, Pd, Pt, Mo, W, Cu, Al alloy or such may be employed. Although being omitted in FIG. 2, the gate electrode 16 is connected to an interconnection layer via a plug or such.

The gate insulating film 12 is made of a silicon oxide, a silicon oxynitride or a silicon nitride with a film thickness of 5 nm, for example. The gate insulating film 12 may be made of high dielectric constant material such as a metallic oxide having a perovskite crystal structure, for example, PZT(Pb(Zr, Ti)O₃) , BaTiO₃, BST(Ba₁₋ₓSrₓTiO₃), SBT(SrBi₂Ta₂O₉) or such. By employing such a high dielectric material, it is possible to increase the actual film thickness while controlling the silicon oxide equivalent thickness, and to increase the electrical leakage withstand voltage between the gate electrode 16 and the carbon nanotube 13.

The carbon nanotube 13 has a diameter in a range between approximately several nanometers and tens of nanometers, may be either of a single-walled carbon nanotube or of a multi-walled carbon nanotube, and, preferably, in terms of seeking more superior transistor characteristics, should be made of a single-walled carbon nanotube or a two-walled carbon nanotube. There, the above-mentioned single-walled carbon nanotube means one having a single layer of Graphene sheet, while the two-walled carbon nanotube means one having two layers of Graphene sheets.

The length of the carbon nanotube 13 is appropriately selected according to a size of the semiconductor device 10, and, for example, is in a range between 30 nm and 1 μm. In terms of seeking miniaturization and increasing the operation speed of the semiconductor device 10, it is preferable to select from a range between 30 nm and 200 nm.

The carbon nanotube is disposed in the longitudinal direction (X direction in FIG. 2) of the gate electrode 16. Disposing of the carbon nanotube 13 may be carried out in such a manner that a previously produced carbon nanotube 13 is disposed, or in such a manner that the carbon nanotube is caused to grow in the longitudinal direction according to a manufacturing method described later.

The source electrode 14 and the drain electrode 15 are made of material same as that of the above-described gate electrode 16, and, are made of, for example, a laminated structure of a Ti film (with a film thickness of 10 nm) and an Au film (with a film thickness of 490 nm). It is preferable that the metal films with which the carbon nanotube 13 directly comes into contact forms ohmic contact, and, for example, it is preferable to employ Ni, Ti, Pt, Pd, Au, or Pt—Au alloy therein.

The source electrode 14 and the drain electrode 15 are formed approximately on both sides of the carbon nanotube 13. It is possible that both ends of the carbon nanotube 13 are made to be open ends, and thereby, contact resistance of the source electrode and drain electrode with the carbon nanotube 13 can be reduced. It is also possible that the carbon nanotube 13 passes through the source electrode 14b and the drain electrode 15.

In the semiconductor device 10 according to the present embodiment, the carbon nanotube 13 is formed above the gate electrode 16 and the gate insulating film 12. Thereby, it is possible to avoid a damage, for example, formation of a defective open hole, otherwise occurring due to plasma or radical in a sputtering method or a CVD method if the gate insulating film were formed after formation of the carbon nanotube 13. As a result, the carbon nanotube 13 in the present embodiment keeps superior electron mobility characteristics.

Furthermore, in the semiconductor device 10 according to the present embodiment, the carbon nanotube 13 is formed on a flat surface of the gate insulating film 12. Thereby, bending deformation otherwise occurring in the carbon nanotube 13 due to a step structure from the source electrode 14 or the drain electrode 15 does not occur. As a result, deterioration in electric characteristics or reliability otherwise occurring due to bending deformation can be positively avoided, and also, it is possible to control increase in the contact resistance between the electrodes and the carbon nanotube 13.

Furthermore, in the semiconductor device 10 in the present embodiment, the gate electrode 16 is formed in the groove 11a in the surface of the substrate 11 having high resistance or insulating property, and the carbon nanotube 13 is formed via the gate electrode 16 and the gate instating film 12. Therefore, in comparison to a semiconductor device in a back gate structure in the related art in which a low resistance substrate is inserted between a gate electrode and a carbon nanotube, it becomes not necessary to perform isolation in the thickness direction of the substrate, and also, a selection range for the substrate material can be broadened.

A method of manufacturing the semiconductor device according to the first embodiment of the present invention described above is described next.

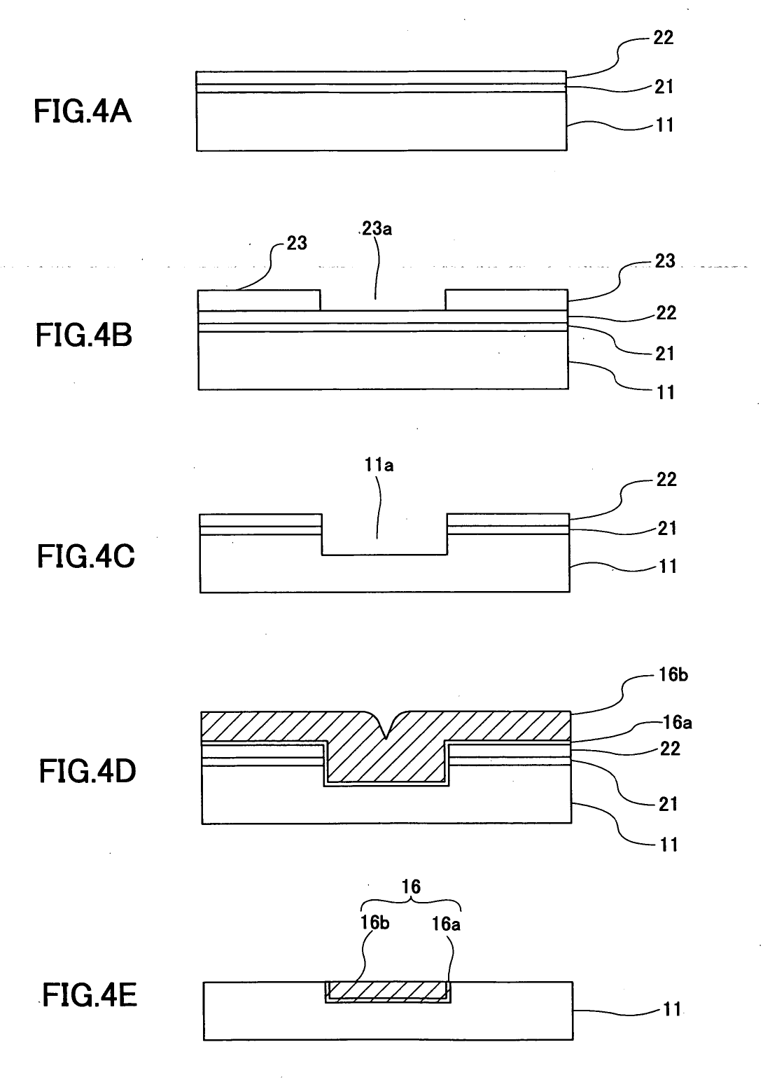

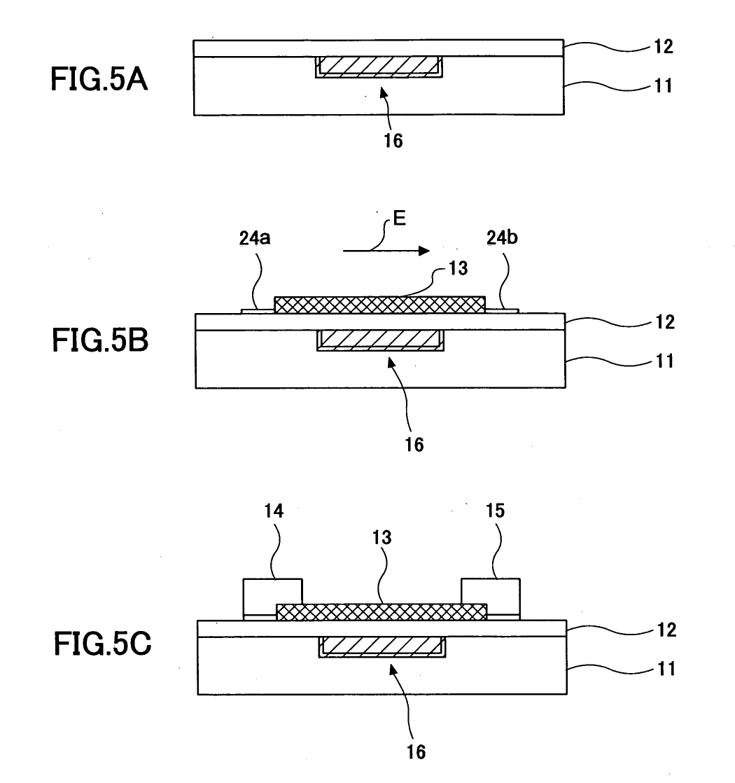

FIGS. 4A through 4E and 5A through 5C illustrate manufacturing processes for the semiconductor device 10 according to the first embodiment.

In a process shown in FIG. 4A, first, a silicon oxide 21 with a film thickness of 10 nm, for example, is formed on the substrate 11, for example, a silicon substrate having a high resistivity by a thermal oxidation method. Then, thereon, a silicon nitride 22 with a thickness of 100 nm, for example, is formed by a sputtering method.

Then, in a process of FIG. 4B, with the use of a photolithography method, a resist film 23 with a thickness of 500 nm is formed on the silicon nitride 22, and an opening 23a is formed in an area in which a groove is formed in the substrate 11 surface in a subsequent process.

Then, in a process of FIG. 4C, with the use of the resist film 23 patterned in the process of FIG. 4B as a mask, the silicon nitride 22 and the silicon oxide 21 are patterned by an ion milling method. Then, the resist film 23 is removed, and, with the use of the silicon nitride 22 and the silicon oxide 23 as a mask, the substrate 11 is grinded to a depth of on the order of 500 nm by an RIE method, so as to form the groove 11a.

Then, in a process of FIG. 4D, a Ti film 16a with a film thickness of 10 nm is formed on the surface of the structure obtained from the process of FIG. 4C by a sputtering method. Further, an Au film 16b with a film thickness of 600 nm is formed to fill the groove 11a by a sputtering method, a deposition method, a CVD method or such.

Then, in a process of FIG. 4E, the Au film 16b formed on the surface in the structure of FIG. 4D is planarized with the use of the silicon nitride 22 as an etching stopper by a CMP (chemical mechanical polishing) method. Thereby, the surface of the substrate 11 is exposed except the area of the groove 11a.

Then, in a process of FIG. 5A, a gate oxide film 12 made of a silicon oxide with a thickness of 5 nm, for example, covering the structure of FIG. 4E is formed by a sputtering method, a CVD method or such. Further, in the above-described case where a high dielectric material such as PZT, BST, SBT or such which is metallic oxide having a perovskite crystal structure is employed, a sputtering method, a CVD method, especially, a MOCVD (organic metal CVD) method is used to form the gate insulating film 12. Further, the gate insulating film 12 made from the high dielectric material may be caused to undergo heating processing at 600° C. in an oxidizing atmosphere for example. Thereby, the crystallinity becomes superior so that the dielectric constant increases. In the case where such a metallic oxide having a perovskite crystal structure is used in the gate insulating film 12, Pt is preferable as a material of the gate electrode. In Pt, a crystal growth direction (film thickness direction) is on a (111) plane as a result of self organizing, and, thereon, a (111) plane of a metallic oxide having a perovskite crystal structure can be caused to carry out epitaxial growth. Thereby, it is possible to improve the crystallinity of the metallic oxide and to increase the dielectric constant.

Then, in a process of FIG. 5B, although not shown, a resist having openings at positions at which the source electrode and the drain electrode are formed in a subsequent process are formed by a photolithography method, and, catalyst layers 24a and 24b each with a film thickness in a range between several nanometers and tens of nanometers made from any one of Co, Ni, Pd and an alloy thereof are formed by a sputtering method.

In a process of FIG. 5B, further, with the use of a thermal CVD method, the structure is heated to approximately 600° C., and also, hydrocarbon gas, for example, acetylene, methane or such used as material gas and a hydrogen gas used as carrier gas are supplied at a pressure of 1 kPa. Further, an electric field is applied in a direction lying between the two catalyst layers 24a and 24b. As a result, a carbon nanotube 13 is formed between the catalyst layers 24a and 24b. Plane shapes of the catalyst layers 24a and 24b can be selected as being arbitrary ones. For example, the catalyst layer 24a may preferably have a sharp extending end in a direction toward the catalyst layer 24b, while the catalyst layer 24b may preferably have a sharp extending end in a direction toward the catalyst layer 24a. Thereby, the carbon nanotube 13 becomes easy to grow from these sharp ends, and a root of the carbon nanotube 13 approximately comes into contact with the gate insulating film. As a result, it is possible to avoid bending deformation of the carbon nanotube 13.

Then, in a process of FIG. 5C, a resist film (not shown) covering the surface of the structure of FIG. 5B is formed, and openings (not shown) are formed therein at positions at which the source electrode 14 and the drain electrode 15 are formed. Then, in a sputtering method, Ti films and Au films are formed, and then, the resist film is removed (lifted off). Thereby, the semiconductor device according to the first embodiment shown in FIG. 5C is completed.

In the process of FIG. 5B, alternatively, it is also possible to dispose a carbon nanotube 13, which is previously produced by a well-known arc discharge method, a laser ablation method or such, on the gate insulating film 12. Specifically, a lifting up method in which, with the use of dispersion in which a carbon nanotube 13 is dispersed in solvent of alcohol such as methanol, water, organic solvent or such, the structure of FIG. 5A is immersed in the dispersion, and then, the structure is lifted up; a liquid surface lowering method in which, the liquid surface of the same dispersion is lowered by means of evaporation instead after the structure is immersed in the dispersion; or a spin coating method in which the same dispersion is coated in a rotation manner or such, may be applied to dispose the carbon nanotube 13. Thus, the carbon nanotube 13 is disposed on the structure of FIG. 5A. As a result, it is possible to dispose the carbon nanotube 13 on the flat surface of the gate insulating film 12.

In the manufacturing method for the semiconductor device according to the present embodiment, since the gate insulating film 12 is formed before the carbon nanotube 13 is formed, it is not necessary to consider damage otherwise applied on the carbon nanotube 13 when the gate insulating film 12 is formed. Thus, it is possible to select a manufacturing method to improve the film quality or such of the insulating film 12.

Although not shown, in a case where a multilayer interconnection structure is produced, interlayer dialectics or such are formed. At this time, in order to avoid damage otherwise applied to the carbon nanotube 13, it is preferable to apply a sol-gel process or such in forming the interlayer dielectric or such on the surface of the semiconductor device 10.

A second embodiment of the present invention is described next.

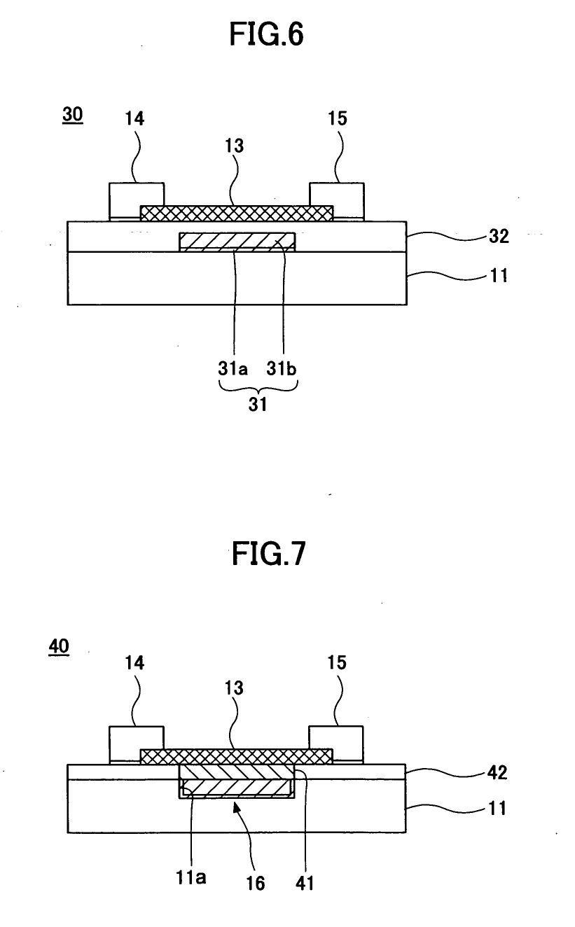

FIG. 6 shows an elevational sectional view of a semiconductor device in a second embodiment of the present invention. In the figure, the same reference numerals are given to parts corresponding to those described above for the first embodiment, and duplicated description is omitted.

As shown in FIG. 6, the semiconductor device 30 according to the second embodiment includes a substrate 11, a gate electrode 31 formed on a surface of the substrate 11, a gate insulating film 32 covering the surface of the substrate 11 and the gate electrode 31, a carbon nanotube 13 formed on the gate insulating film 32 in such a manner that the length direction of the gate electrode coincides with the longitudinal direction of the carbon nanotube 13, and a source electrode 14 and a drain electrode 15 formed on the gate insulating film 32 apart from one another in the longitudinal direction of the carbon nanotube 13 and electrically connected with the carbon nanotube 13.

In the semiconductor device 30 in the second embodiment, instead of the gate electrode 16 being embedded in the substrate 11 in the first embodiment, the gate electrode 31 is formed on the substrate 11. Except this point, the second embodiment is identical to the first embodiment.

The gate electrode 31 may be made from the same material as that in the first embodiment, i.e., for example, may be made of a laminated structure of a Ti film 31a and an Au film 31b. A film thickness of the gate electrode 31 is preferably in a range between 1 nm and 20 nm in terms of flatness of a surface of the gate insulating film 32 formed thereon. For example, the film thickness of the Ti film 31a is set as 5 nm while the film thickness of the Au film 31b is set as 95 nm.

The gate insulating film 32 may be made from the same material as that in the first embodiment, and may be made of a silicon oxide, a silicon oxynitride, a silicon nitride or a metal-oxide high dielectric material having a perovskite crystal structure. The gate insulating film 32 may be preferably made from a high dielectric material in which it is possible to increase a film thickness while controlling increase in silicon oxide equivalent thickness, in terms of covering characteristic for the gate electrode 31. Thereby, it is possible to increase an electrical leakage withstand voltage between the gate electrode 31 and the carbon nanotube 13. Furthermore, simultaneously, it is possible to planarize the surface of the gate insulating film 32 so as to avoid bending deformation of the carbon nanotube 13.

In a manufacturing method for the semiconductor device 30 in the second embodiment, instead of the processes of FIGS. 4A through 4E in the first embodiment, a resist film is formed on the substrate 11, an opening is formed therein by patterning for an area to form the gate electrode 31 in a photolithography method; and the gate electrode 31 made of the laminated structure of the Ti film 31a and the Au film 31b is formed on the surface of the substrate 11 by a sputtering method. Then, the gate insulating film 32 covering the surface of the substrate 11 and the gate electrode 31 is formed by a sputtering method, a CVD method or such. After that, the processes same as those of FIGS. 5B and 5C are carried out. Thereby, the semiconductor device 30 in the second embodiment is completed.

In the above-described manufacturing method for the semiconductor device 30 in the second embodiment, in addition to the advantages obtained from the case for the first embodiment, since no groove is formed in the second embodiment, it is possible to reduce the number of processes in comparison to the case for the semiconductor device in the first embodiment.

A third embodiment of the present invention is described next.

FIG. 7 shows an elevational sectional view of a semiconductor device in a third embodiment of the present invention. In the figure, the same reference numerals are given to parts corresponding to those described above for the first and second embodiments, and duplicated description is omitted.

As shown in FIG. 7, the semiconductor device 40 according to the third embodiment includes a substrate 11, a gate electrode 16 formed in a groove 11a formed in a surface of the substrate 11, a high dielectric gate insulating film 41 formed on the gate electrode 16, an insulating film 42 formed on the substrate 11 surface except the area of the gate electrode 16, a carbon nanotube 13 formed on the high dielectric gate insulating film 41 and the insulating film 42 in such a manner that the length direction of the gate electrode coincides with the longitudinal direction of the carbon nanotube 13, and a source electrode 14 and a drain electrode 15 formed on the insulating film 42, apart from one another in the longitudinal direction of the carbon nanotube 13 and electrically connected with the carbon nanotube 13.

Except that the gate insulating film in the above-described first embodiment is replaced by the high dielectric insulating film 41 employing a high dielectric material for the area right above the gate electrode, the semiconductor device 40 in the third embodiment is configured to be the same as the semiconductor device in the first embodiment.

The high dielectric gate insulating film 41 is formed employing the high dielectric material described above for the first and second embodiments. Since the thickness of the high dielectric insulating film 41 can be increased, it is possible to easily improve the film quality, and also, by employing the high dielectric insulating film 41, it is possible to increase the gate capacitance so as to reduce the gate voltage. The insulating film 42 may be made from a covalent material such as a silicon oxide, a silicon oxynitride, a silicon nitride or such, or a material having a dielectric constant lower than that of the high dielectric gate insulating film, from among the possible materials for the gate electrode described above for the first embodiment. Since the above-mentioned high dielectric material is an electrovalent bond material, electrical leakage may occur easily when a defect such as oxygen deficiency occurs. By employing the covalent material for the instating film, it is possible to increase the electrical leakage withstand voltage.

In a manufacturing method for the semiconductor device 40 in the third embodiment, after the same processes as those of FIGS. 4A through 4E for the first embodiment are carried out, the resist film formed on the surface of the structure of FIG. 4E is patterned so that it covers only the area right above the gate electrode 16. Then, the insulating film 42 is formed with the use thereof by a sputtering method or such. Then, the resist film is lifted off so that the surface of the gate electrode is exposed, and, thereon, the high dielectric gate insulating film 41 is formed with the use of a high dielectric material by a sputtering method, a CVD method or such. Then, the surface of the high dielectric insulating film 41 is planarized, and also, a surface of the insulating film 42 is exposed. Then, the same processes as those of FIGS. 5B and 5C are carried out. Thereby, the semiconductor device 40 in the third embodiment shown in FIG. 7 is completed.

In the semiconductor device 40 in the third embodiment, in addition to the advantages obtained from the case for the semiconductor device in the first embodiment, since the high dielectric insulating film 41 employing the high dielectric material is formed as the gate insulating film 41, it is possible to reduce the gate voltage. Further, since the covalent insulating film 42 such as a silicon oxide or such is formed between the gate electrode and the source electrode and between the gate electrode and the drain electrode, it is possible to increase the electrical leakage withstand voltage between the gate electrode 16 and the source electrode 14 and between the gate electrode 16 and the drain electrode 15.

A fourth embodiment of the present invention is described next.

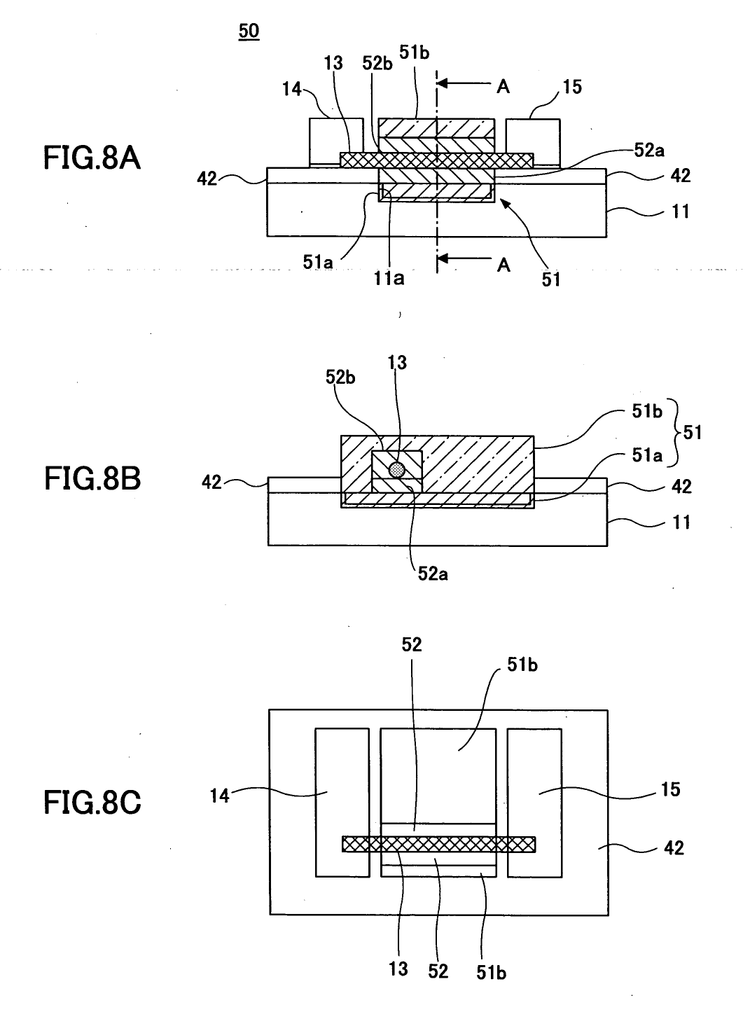

FIGS. 8A, 8B and 8C show a semiconductor device in the fourth embodiment of the present invention. FIG. 8A shows an elevational sectional view, FIG. 8B shows a sectional view taken along an A-A line shown in FIG. 8A and FIG. 8C shows a plan view. In the figures, the same reference numerals are given to parts corresponding to those described above for the first through third embodiments, and duplicated description is omitted.

As shown in FIGS. 8A through 8C, the semiconductor device 50 according to the fourth embodiment includes a substrate 11, a lower gate electrode 51a formed in a groove 11a formed in a surface of the substrate 11, a lower high dielectric gate insulating film 52a formed on the lower gate electrode 51a, an insulating film 42 formed on the substrate 11 surface except the area of the lower gate electrode 51a, a carbon nanotube 13 formed on the lower high dielectric gate insulating film 52a and the insulating film 42 in such a manner that the length direction of the gate electrode coincides with the longitudinal direction of the carbon nanotube 13, an upper high dielectric gate insulating film 52b covering a surface of the lower high dielectric gate insulating film 52a and the carbon nanotube 13, an upper gate electrode 51b covering the lower high dielectric gate insulating film 52b and coming into contact with the lower gate electrode 51a, and a source electrode 14 and a drain electrode 15 formed on the insulating film 42, apart from one another in the longitudinal direction of the carbon nanotube 13 and electrically connected with the carbon nanotube 13.

That is, the semiconductor device 50 is different from the semiconductor device 40 in the third embodiment shown in FIG. 7 in that the upper high dielectric gate insulating film 52b is formed to cover the carbon nanotube 13, further the upper gate electrode 51b covering the upper high dielectric gate insulating film 52b is formed, so that a gate electrode 51 including the lower gate electrode 51a and the upper gate electrode 51b surrounds the carbon nanotube 13. Except this point, the semiconductor device 50 in the fourth embodiment is configured to be approximately same as the semiconductor device 40 in the third embodiment.

The lower gate electrode 51a and the upper gate electrode 51b may be made from material same as that of the gate electrode in the first embodiment described above. Further, the lower high dielectric gate insulating film 52a and the upper high dielectric gate insulating film 52b may be made of material same as that of the high dielectric insulating film in the third embodiment described above.

In the semiconductor device 50 in the fourth embodiment, the carbon nanotube 13 is surrounded by the gate electrode 51 via a high dielectric gate insulating film 52 including the lower high dielectric gate insulating film 52a and the upper high dielectric gate insulating film 52b. Thereby, an electric field created according to the gate voltage is efficiently applied to the entirety of the carbon nanotube 13. Accordingly, in comparison to the third embodiment, it is possible to further increase the gate capacitance and thus to reduce the gate voltage.

A fifth embodiment of the present invention is described next.

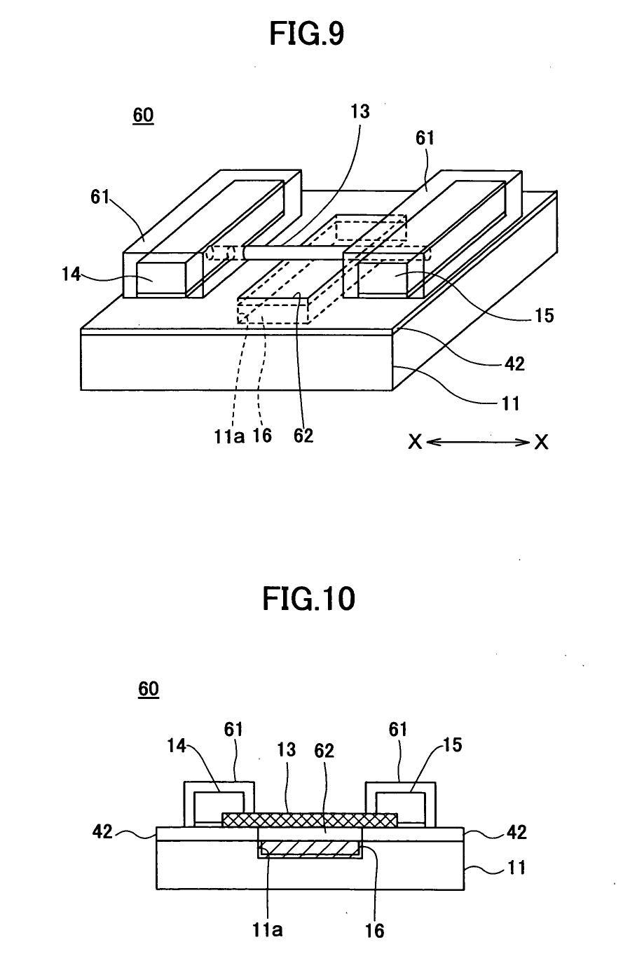

FIG. 9 shows a perspective view of a semiconductor sensor 60 in the fifth embodiment of the present invention, and FIG. 10 shows an elevational sectional view of the semiconductor sensor 60. In the figures, the same reference numerals are given to parts corresponding to those described above for the first through fourth embodiments, and duplicated description is omitted.

As shown in FIGS. 9 and 10, the semiconductor sensor 60 according to the fifth embodiment includes a substrate 11, a gate electrode 16 formed in a groove 11a formed in a surface of the substrate 11, an insulating film 42 covering a surface of the substrate 11 and a part of the gate electrode 16, a carbon nanotube 13 formed on the insulating film 42 in such a manner that the length direction of the gate electrode 16 coincides with the longitudinal direction of the carbon nanotube 13, a source electrode 14 and a drain electrode 15 formed on the insulating film 42, apart from one another in the longitudinal direction of the carbon nanotube 13 and electrically connected with the carbon nanotube 13, and an protective film 61 covering each of the source electrode 14 and the drain electrode 15. The insulating film 42 has an empty space 62 below the carbon nanotube 13, which exposes the surface of the gate electrode 16.

That is, in the semiconductor sensor 60, the empty space 62 exposing the surface of the gate electrode 16 is formed without forming the insulting film 42 in an area right above the gate electrode 16, in a structure approximately same as that of the semiconductor device according to the first embodiment. Also, the protective films 62 are provided to cover the source electrode 143 and the drain electrode 15, respectively.

The insulating film 42 may be made of a silicon oxide, a silicon oxynitride, a silicon nitride or such, and, should not be limited thereto. A film thickness of the insulating film 42 is, for example, set as 1 nm. Further, the empty space 62 formed in the insulating film 42 is provided below the carbon nanotube 13, and exposes the surface of the gate electrode 16. However, it is not necessary that the empty space 62 should expose the entirety of the top surface of the gate electrode 16. The empty space 62 may have a size of, for example, in a range between 0.5 μm and 3 μm in the longitudinal direction of the carbon nanotube 13, and in a range between 0.5 μm and 3 μm in the width direction.

The protective films 61 are made from inorganic material such as silicon nitrides or resin films such as polyimide films having water nonpermeability. These protective films 62 avoid electrical leakage otherwise occurring from the source electrode 14 and the drain electrode 15 through liquid or such which is a to-be-measured object, and also, avoid corrosion of the source electrode 14 and the drain electrode 15.

In the semiconductor sensor 60 in the fifth embodiment, as a result of the surface thereof being exposed to liquid or gas as a to-be-measured object (simply referred to as ‘liquid or such’, hereinafter), due to influence of ions or dielectric matters contained in the liquid or such inserted in the empty space 62 provided in the insulating film 42, i.e., inserted between the surface of the gate electrode 16 and the carbon nanotube 13, the dielectric constant there changes, thereby the gate capacitance changes, and as a result, the drain current changes. For example, by setting the gate voltage above the threshold voltage, and setting the drain voltage in a saturation current zone in the drain current-drain voltage characteristics, it is possible to detect the change in the dielectric constant as a corresponding change in the drain current. Since the gate capacitance value and the drain current change approximately in proportion to the change in the dielectric constant, it is possible to detect the change in the dielectric constant at high accuracy. In the semiconductor sensor 60 in the fifth embodiment of the present invention, since the carbon nanotube 13 is chemically stable, and also, has a high mechanical strength, it has a high reliability.

In a manufacturing method for the semiconductor sensor 60 in the fifth embodiment, after the same processes as those of FIGS. 4A through 4E are carried out, the resist film formed on the surface of the structure of FIG. 4E is patterned so that it may cover only the area right above the gate electrode 16 or may cover only a part of the top surface thereof. Then, the insulating film 42 is formed with the use thereof by a sputtering method or such. Then, the resist film is lifted off so that the empty space 62 exposing the surface of the gate electrode 16 is created. Then, the same processes as those of FIGS. 5B and 5C are carried out. Further, the protective films 61 covering the source electrode 14 and the drain electrode 15 respectively are formed. Thereby, the semiconductor sensor 60 in the fifth embodiment shown in FIGS. 9 and 10 is completed.

In the semiconductor sensor 60 in the fifth embodiment of the present invention, the empty space 62 is provided instead of the gate insulating film between the gate electrode 16 and the carbon nanotube 13, and a change in the dielectric constant therebetween due to a to-be-measured object existing in the empty space 62 is directly detected. Thus, in comparison to a case where the gate insulating film were provided there, it is possible to achieve the detection at a higher sensitivity.

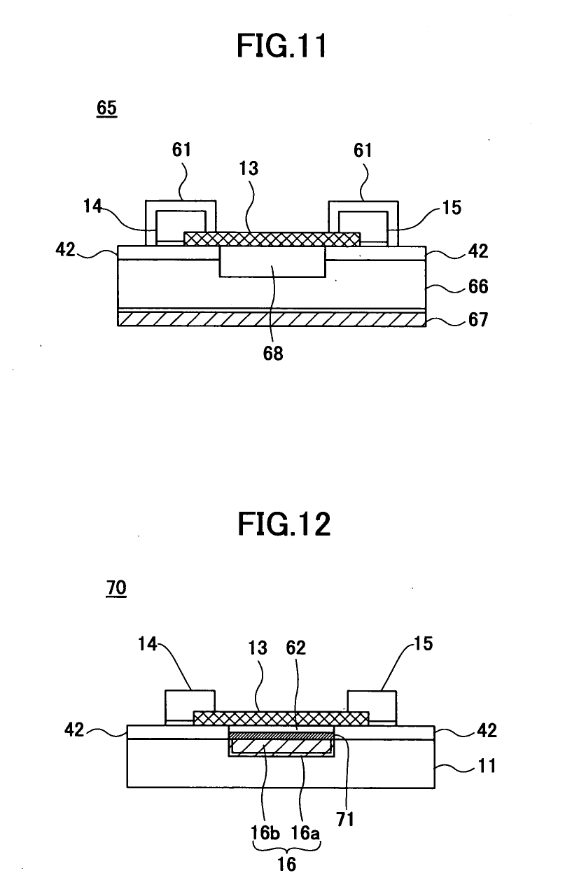

FIG. 11 shows an elevational sectional view of a semiconductor sensor in a variant embodiment of the above-described fifth embodiment of the present invention.

As shown in FIG. 11, in the semiconductor sensor 65 in the variant embodiment of the fifth embodiment, the gate electrode 16 (67, in the sensor 65) which is embedded in the surface of the substrate 11 of the semiconductor sensor in the fifth embodiment shown in FIGS. 9 and 10, is formed instead on the reverse side of the substrate 11. Further, the substrate 11 becomes a substrate 66 having a low specific resistance. Except these matters, the semiconductor sensor 65 in the variant embodiment of the fifth embodiment has the same configuration as that of the semiconductor device 60 in the fifth embodiment.

A material of the substrate 66 is not specifically limited, as long as it has a low specific resistance, and, for example, the substrate 66 is made of a silicon substrate having a low specific resistance and having a thickness of 500 μm. The gate electrode 67 is formed on the reverse side of the substrate 66 and is made of the same material as that of the gate electrode 16 in the fifth embodiment. For example, the gate electrode 67 is made of a Ti film and an Au film laminated in the stated order from the surface of the reverse side of the substrate 66. When a voltage is applied to the gate electrode 67, the substrate 66 has the same voltage as that of the gate electrode 67, and the substrate 66 also acts as a gate electrode.

Further, a groove 68 is formed below the carbon nanotube 13 in the obverse side surface of the substrate 66, as shown. Alternatively, it is also possible, not to provide such a groove 68 in the obverse side surface of the substrate 66, but to create an empty space provided only in the insulating film 42. In the groove 68 (or the above-mentioned empty space), as a result of liquid or such of a to-be-measured object entering there, and being inserted between the surface of the substrate 66 and the carbon nanotube 13, it is possible to detect molecules or such contained in the liquid or such existing on the gate electrode 68 exposed in the groove 68 (or in the empty space).

In the semiconductor sensor 65 in the variant embodiment, as a result of the gate electrode 67 being provided on the reverse side of the substrate 66, the gate electrode 67 is prevented from being exposed to the liquid or such, and also, electrical connection with the gate electrode 67 can be made easier.

A sixth embodiment of the present invention is described next.

FIG. 12 shows an elevational sectional view of a semiconductor sensor 70 in the sixth embodiment of the present invention. The same reference numerals are given to parts corresponding those already described, and the duplicated description is omitted.

As shown in FIG. 12, in the semiconductor sensor 70 in the sixth embodiment, a sticking film 71 for selectively causing to-be-maturated object to stick thereto is formed on the surface of the gate electrode 16 exposed in the empty space 62 in the semiconductor sensor in the fifth embodiment shown in FIGS. 9 and 10. Except these mattes, the semiconductor sensor in the sixth embodiment has the same configuration as that of the semiconductor sensor in the fifth embodiment.

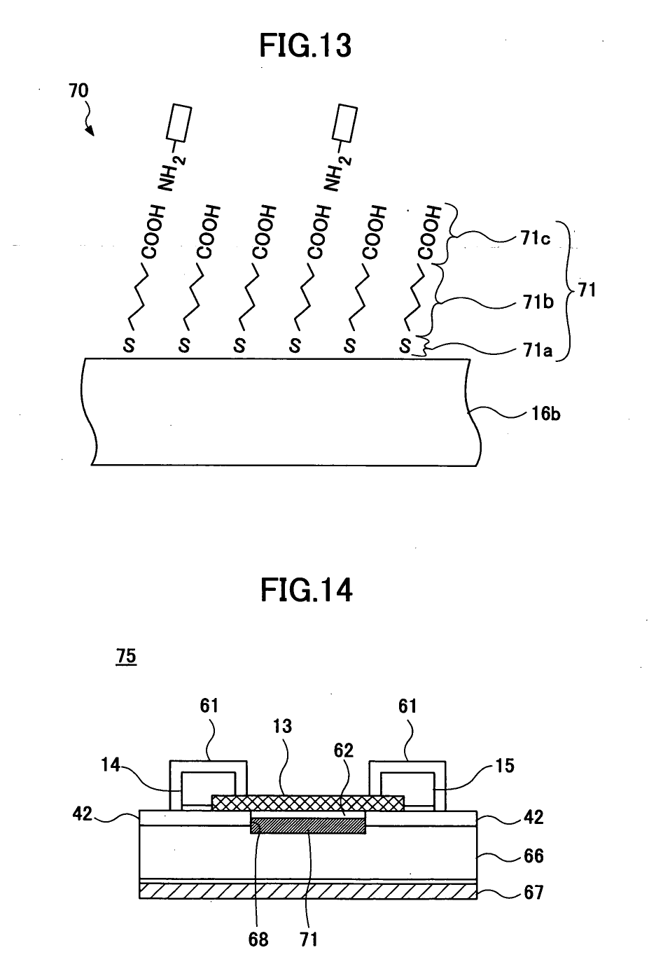

FIG. 13 shows a partial magnified view of the above-mentioned semiconductor sensor 70 in the sixth embodiment. As shown, the sticking film 71 includes a primary bonding part 71a including atoms or molecules which bond to the surface of the Au film 16b of the gate electrode 16, a molecular chain part 71b including alkyl chains or such extending from the primary bonding part 71a, and a functional part 71c including functional groups such as carboxyl groups bonding to an end of the molecular chain part 71b on a side opposite to the side of the primary bonding part 71a. In the sticking film 71, as a result of the surface of the semiconductor sensor 70 being exposed to liquid or such of to-be-measured object, the functional part 71c reacts with and thus bonds to various molecules or such contained in the liquid or such so as to fix the molecules or such thereto, and as a result, the dielectric constant changing due to the molecules or such can be detected as a change in the drain current as in the fifth embodiment described above at high sensitivity.

The primary bonding part 71a includes a self assembled monolayer (SAM) formed by a so-called self-organizing map method. For this purpose, for example, a SAM having alkyl chains (molecular chain part) in which alkanethiol compound is caused to react with the Au surface so as to form Au—S bonding and is highly orientated, may be applied.

As an example of end functional groups in the functional part 71c, carboxyl groups, amino groups, Fmoc groups (9-fluorenylmethyloxy-carbonyl groups) or ferrocenyl groups may be applied. For example, in a case where the functional part includes carboxyl groups, it is possible to fix thereto peptide, protein or such having amino groups by amide bond.

As an example of the alkanethiol compound used to form the sticking film 71, 10-carboxyl-1-decanethiol having a carboxyl group as the end functional group or 11-ferrocenyl-1-undecanethiole (provided by Dojindo Laboratories Co. Ltd., for example) having a ferrocenyl group as the end functional group, may be applied.

It is preferable that the sticking film 71 has a thickness of on the order of 100 nm, and the empty space in a range between 10 nm and 100 nm is provided between the sticking film 71 and the carbon nanotube 13. Thereby, it becomes possible to detect change in the dielectric constant due to molecules or such sticking to the functional part 71c with a further higher sensitivity.

In the semiconductor sensor 70 in the sixth embodiment, as a result of the sticking film 71 being formed on the surface of the gate electrode between the gate electrode 16 and the carbon nanotube 13 instead of provision of the gate insulating film there, it is possible to selectively fixing molecules thereto. Thereby, it is possible to directly detect the dielectric constant which changes according to the amount of the to-be-measured molecules or such thus fixed thereto, and thus, it is possible to positively detect the amount of the to-be-measured molecules or such with a high sensitivity.

FIG. 14 shows an elevational sectional view of a semiconductor sensor 75 in a variant embodiment of the sixth embodiment of the present invention. As shown, in the semiconductor sensor 75 in the variant embodiment, the gate electrode 16 (67 in this embodiment) embedded in the surface of the substrate 11 of the semiconductor sensor in the sixth embodiment shown in FIG. 12 is instead formed on the reverse side of the substrate 66. Also, the substrate 66 is of a low specific resistance, and also, a sticking film 71 is formed in a groove 68 formed in the surface of the substrate 66 as shown. Except these matters, the semiconductor sensor 75 in the variant embodiment has the same configuration as that of the semiconductor sensor in the sixth embodiment. Alternatively, without forming the groove 68 in the surface of the substrate 66, it is possible to create an empty space 62 only in the insulating film 42, and to form a sticking film 71 on the surface of the substrate 71 there.

In the semiconductor sensor 75 in the variant embodiment, in addition to the advantages of the semiconductor sensor in the sixth embodiment, it is possible to avoid the gate electrode 67 from being exposed to the liquid or such by forming the gate electrode 67 on the reverse side of the substrate 66, and also, it is possible to achieve easy electrical connection with the gate electrode 67.

Further, the present invention is not limited to the above-described embodiments, and variations and modifications may be made without departing from the basic concept of the present invention claimed below.

The present application is based on Japanese Priority Application No.2004-093076, filed on Mar. 26, 2004, the entire contents of which are hereby incorporated by reference.

1. A semiconductor device comprising:
a substrate;
a gate electrode formed on said substrate;
a gate insulating film covering said gate electrode;
a carbon nanotube disposed above said gate electrode and coming into contact with said gate insulating film; and
a source electrode and a drain electrode formed apart from one another in a longitudinal direction of said carbon nanotube and electrically connected with said carbon nanotube.

2. The semiconductor device as claimed in claim 1, wherein:
said gate electrode is formed on a surface of said substrate; and
said gate insulating film covers the substrate surface and said gate electrode, and also, has an approximately flat surface.

3. The semiconductor device as claimed in claim 1, wherein:
said gate electrode is embedded in a groove formed in the substrate surface.

4. The semiconductor device as claimed in claim 3, wherein:
said substrate surface and said gate electrode surface are approximately flush with one another.

5. The semiconductor device as claimed in claim 1, wherein:
said gate insulating film comprises a first gate insulating film located above said gate electrode and a second insulting film located in an area other than said first gate insulting film; and
said first insulating film has a dielectric constant higher than that of said second insulating film.

6. The semiconductor device as claimed in claim 5, wherein:
said first gate insulating film comprises a metallic oxide having a perovskite structure.

7. The semiconductor device as claimed in claim 5, wherein:
said second gate insulating film comprises covalent inorganic material.

8. The semiconductor device as claimed in claim 5, further comprising:
a third gate insulating film covering said first gate installing film surface and said carbon nanotube; and
another gate electrode covering said third gate insulating film and also coming into contact with said gate electrode, wherein:
said gate electrode and said another gate electrode are formed in such a manner as to surround said carbon nanotube via said first gate insulating film and said third gate insulting film.

9. The semiconductor device as claimed in claim 8, wherein:
said third insulating film is made from material same as that of said first gate insulating film.

10. A semiconductor sensor comprising:
a substrate;
a gate electrode formed on said substrate;
an insulating film covering a surface of said substrate and a part of said gate electrode;
a carbon nanotube disposed to come into contact with said insulating film; and
a source electrode and a drain electrode formed apart from one another in a longitudinal direction of said carbon nanotube, and electrically coming into contact with said carbon nanotube, wherein:
said insulating film comprises an empty space part between said gate electrode and said carbon nanotube for exposing a surface of said gate electrode.

11. The semiconductor sensor as claimed in claim 10, further comprising:
a sticking layer for sticking a to-be-measured object thereto on the surface of said gate electrode thus exposed.

12. A semiconductor sensor comprising:
a substrate;
an insulating film covering a partial area of a surface of said substrate;
a carbon nanotube disposed to come into contact with said insulating film;
a source electrode and a drain electrode formed apart from one another in a longitudinal direction of said carbon nanotube and electrically coming into contact with said carbon nanotube; and
a gate electrode formed on a reverse side of said substrate, wherein:
said insulating film comprises an empty space right below said carbon nanotube to expose a surface of said substrate.

13. The semiconductor sensor as claimed in claim 12, further comprising:
a sticking layer for sticking a to-be-measured object thereto on the surface of said gate electrode exposed in said empty space.

14. The semiconductor sensor as claimed in claim 11, wherein:
said sticking layer has a functional part selectively fixing the to-be-measured object at a molecular chain end.

15. The semiconductor sensor as claimed in claim 13, wherein:
said sticking layer has a functional part selectively fixing the to-be-measured object at a molecular chain end.

16. The semiconductor sensor as claimed in claim 10, further comprising:
a protective layer covering each of said source electrode and said drain electrode.

17. The semiconductor sensor as claimed in claim 12, further comprising:
a protective layer covering each of said source electrode and said drain electrode.
